(19) United States
(12) Patent Application Publication
(10) Pub. No.: US 2002/0040982 A1
(43) Pub. Date: Apr. 11, 2002

(54) Light emitting unit

(76) Inventor: Toshiya Uemura, Nishikasugai-gun (JP)

Correspondence Address: PILLSBURY WINTHROP LLP, 1600 TYSONS BOULEVARD, MCLEAN, VA, 22102, US

(21) Appl. No.: 09/953,825

(22) Filed: Sep. 18, 2001

(30) Foreign Application Priority Data
Sep. 29, 2000 (JP) P.2000-298249

(51) Int. Cl. H01L 27/15

(52) U.S. Cl. 257/80

(57) ABSTRACT

A mount frame is provided with a recess portion and a light-transmissible member charged into the recess portion. A sapphire substrate of a light-emitting device is fixed to the surface of the light-transmissible member. Thus, light transmitted through the sapphire substrate is transmitted through the light-transmissible member, reflected by the surface of the recess portion, further transmitted through the light-transmissible member, and emitted to the outside of the recess portion.

### BACKGROUND OF THE INVENTION

1. Field of the Invention

The present invention relates to an improvement of a light-emitting unit mounted with a group III nitride compound semiconductor light-emitting device.

The present application is based on Japanese Patent Application No. 2000-298249, which is incorporated herein by reference.

2. Description of the Related Art

Since an electrically insulating sapphire substrate is used in a group III nitride compound semiconductor light-emitting device, a p-type electrode and an n-type electrode are formed on the surface of a semiconductor layer. These p-type and n-type electrodes shield light generated in the semiconductor layer. Thus, paying attention to the fact that the sapphire substrate is transparent, there has been proposed a structure in which the light-emitting device is mounted on the substrate while the substrate is set on the top side. When such a flip chip is adopted, the light emission efficiency of the light-emitting unit is improved.

In the case of such a flip chip, a sub-mount 5 is interposed between a light-emitting device 1 and a mount frame 3 as shown in FIG. 1. Then, a portion of the sub-mount 5 connected to the p-type electrode is connected to a lead frame 7 through a conductive wire 8. On the other hand, a portion of the sub-mount 5 connected to the n-type electrode is electrically coupled with the mount frame 3. To manufacture the light-emitting unit, the light-emitting device 1 is first mounted on the sub-mount 5, and then, the sub-mount 5 is fixed to the bottom of a cup-like recess portion 4 of the mount frame 3.

In the light-emitting unit configured thus, light generated in the light-emitting device 1 is transmitted wholly through a substrate 2, and emitted to the outside. Thus, the problem that light is shielded by the electrodes of the light-emitting device is solved.

As the light-emitting device involved in the present invention, there is a reflection type LED. Further information about the reflection type LED will be disclosed in Unexamined Japanese Patent Publication No. Hei. 11-177145.

In a light-emitting unit using a flip chip, it is necessary to use a sub-mount as described above. Thus, the number of man-hour in manufacturing increases compared with a type in which a substrate of a light-emitting device is fixed directly to a mount frame.

### SUMMARY OF THE INVENTION

As a result of an investigation made repeatedly by the present inventor to solve such a problem, the present inventor conceived a light-emitting unit having a novel configuration in which light transmitted through a light-transmissible substrate of a light-emitting device is emitted wholly to the outside.

That is, a light-emitting unit constituted by: a mount frame having a reflection surface and a light-transmissible member substantially covering the reflection surface; and a group III nitride compound semiconductor light-emitting device mounted on the mount frame; wherein the substrate of the light-emitting device is fixed to a surface of the light-transmissible member so that light emitted from the light-emitting device is transmitted through the substrate and reflected by the reflection surface.

The light-emitting unit configured thus needs no sub-mount, and the number of man-hour in manufacturing is reduced. It is therefore possible to provide a light-emitting unit at a low price.

Features and advantages of the invention will be evident from the following detailed description of the preferred embodiments described in conjunction with the attached drawings.

### BRIEF DESCRIPTION OF THE DRAWINGS

In the accompanying drawings:

FIG. 1 is a diagram showing the configuration of a light-emitting unit in a conventional example;

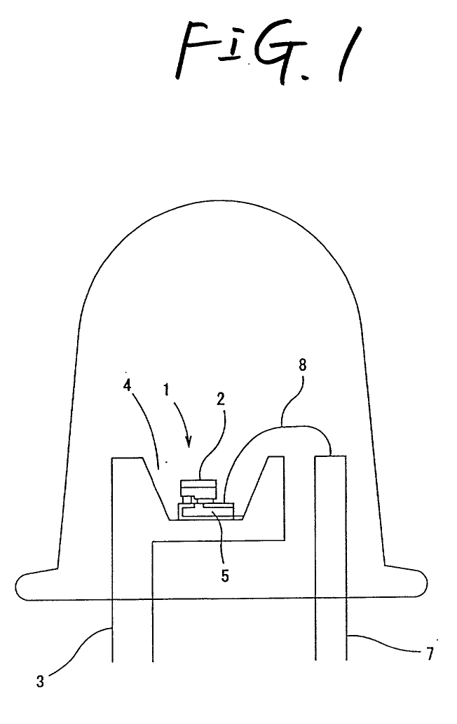

FIG. 2 is a diagram showing the configuration of a light-emitting device according to an embodiment of the present invention;

FIG. 3 is a diagram showing the configuration of a light-emitting unit according to the embodiment of the present invention;

FIG. 4 is a diagram showing the configuration of a light-emitting unit according to another embodiment of the present invention;

FIG. 5 is a diagram showing the configuration of a light-emitting unit according to another embodiment of the present invention;

FIG. 6 is a diagram showing the configuration of a light-emitting unit according to another embodiment of the present invention; and

FIG. 7 is a diagram showing the configuration of a light-emitting unit according to another embodiment of the present invention.

### DETAILED DESCRIPTION OF THE PREFERRED EMBODIMENTS

Constituent parts of the present invention will be described below in detail.

In this specification, each group III nitride compound semiconductor is represented by the general formula: AlₓGa_{y}In_{1-x-y}N (0≦X≦1, 0≦Y≦1, 0≦X+Y≦1) which includes so-called binary compounds such as AlN, GaN and InN, and so-called ternary compounds such as AlₓGa₁₋ₓN, AlₓIn₁₋ₓN and GaₓIn₁₋ₓN (here, 0<x<1) The group III elements may be partially replaced by boron (B), thallium (Tl), or the like. The nitrogen (N) may be partially replaced by phosphorus (P), arsenic (As), antimony (Sb), bismuth (Bi), or the like. The group III nitride compound semiconductor layer may contain an optional dopant. Si, Ge, Se, Te, C, or the like, can be used as n-type impurities. Mg, Zn, Be, Ca, Sr, Ba, or the like, can be used as p-type impurities. Incidentally, the group III nitride compound semiconductor doped with p-type impurities may be irradiated with electron beams or with plasma or heated in a furnace. The method for forming each group III nitride compound semiconductor layer is not particularly limited. For example, the group III nitride compound semiconductor layer may be formed by a metal organic chemical vapor deposition method (MOCVD method) or maybe formed by a well known method such as a molecular beam epitaxy method (MBE method), a halide vapor phase epitaxy method (HVPE method), a sputtering method, an ion-plating method, an electron showering method, etc.

Incidentally, a homo type structure, a hetero type structure, a double hetero type structure may be used as the structure of the light-emitting device. A quantum well structure (single quantum well structure or multiple quantum well structure) may be provided as a layer containing a light-emitting layer.

According to the present invention, the substrate of the light-emitting device is fixed to the light-transmissive member. The substrate of the light-emitting device is not limited specifically so long as a group III nitride compound layer can be grown on the substrate and the substrate is light-transmissible to transmit the light at least from the layer containing the light-emitting layer. Examples of materials of the substrate may include sapphire, spinel (MgAl₂O₄), SiC (including 6H, 4H, and 3C), zincoxide (ZnO), zinc sulfide (ZnS), magnesium oxide, group III nitride compound semiconductor single crystal (GaAs, GaP, etc.), silicon (Si), and soon. Especially, a sapphire substrate is preferably used.

According to the present invention, in the light-emitting device, light from the layer containing light-emitting layer is transmitted wholly through the substrate and emitted to the outside. Thus, an electrode formed on a p-type contact layer does not have to have light transmissivity.

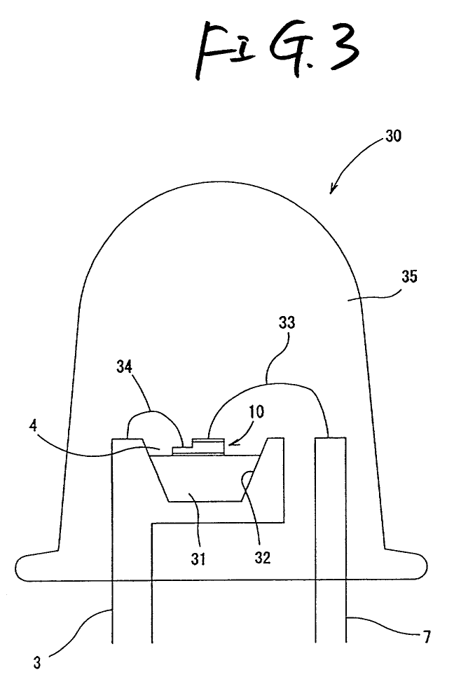

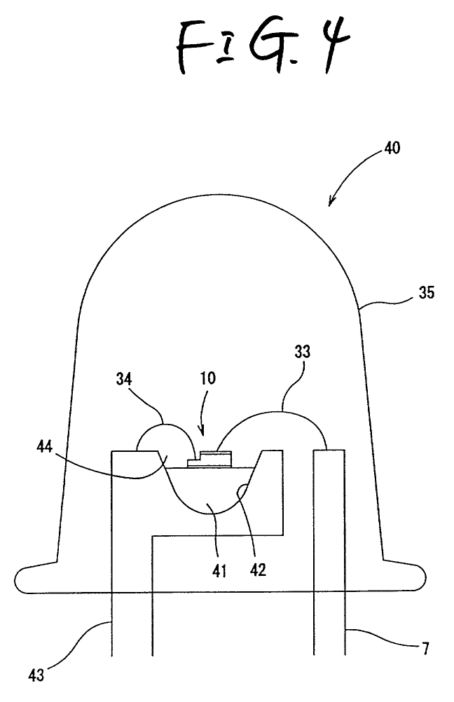

The reflection surface of the mount frame is designed suitably in accordance with the optical properties required of the light-emitting unit. For example, a mount frame in a conventional example can be used directly, as shown in FIG. 3. In FIG. 3, the surface of a cup-like recess portion 4 is formed as a reflection surface. Alternatively, the shape of a recess portion 44 is formed to be a paraboloid of revolution as shown in FIG. 4. Although a recess portion is provided in the mount frame and the surface of the recess portion is formed as a reflection surface in the embodiments of FIGS. 3 and 4, a reflection surface may be provided to be erected separately from the mount frame.

The mount frame is formed by pressing a conductive metal material (for example, iron). To make the reflection surface reflect the light from the light-emitting device efficiently, preferably, the reflection surface is plated with Ag after being polished.

The light-transmissible member is formed out of a material which substantially transmits light supplied from the light-emitting device. Examples of such a material may include transparent resin materials such as epoxy resin, urea resin, etc., or transparent glass such as metal alkoxide-ceramic precursor polymer (Unexamined Japanese Patent Publication No. Hei. 11-204838), etc. It will go well if the light-transmissible material transmits at least light from the light-emitting device and light emitted from a fluorescent material if the fluorescent material is used as will be described later. When a resin material is used as the light-transmissible material, it is preferable that additives such as reinforcers, fillers, coloring agents, pigments, fire retardants, etc. are used together.

The light-transmissible material in fluidity is dropped into the recess portion (on the reflection surface) of the mount frame, and solidified to thereby obtain the light-transmissible member.

It is preferable that the surface of the light-transmissible member is located in a lower position than the opening portion (circumferential edge of the reflection surface) of the recess portion (on this side in the optical axis direction). Thus, a side surface of the light-emitting device is opposed to the reflection surface so that light emitted from the side surface of the light-emitting device is also reflected by the reflection surface and used effectively.

A fluorescent material may be dispersed into the light-transmissible member. By selecting the fluorescent material, light emitted from the layer containing a light-emitting layer can be changed into a desired color.

As the fluorescent material, the following may be used: ZnS:Cu, Au, Al; ZnS:Cu, Al; ZnS:Cu; ZnS:Mn; ZnS:Eu; YVO₄:Eu; YVO₄:Ce; Y₂O₂S:Eu; and Y₂O₂S:Ce. One or two fluorescent materials selected from these examples of fluorescent materials can be used. Here, ZnS:Cu, Au, Al designates a ZnS photoluminescence fluorescent material having ZnS as a parent body and activated by Cu, Au and Al. Likewise, ZnS:Cu, Al; ZnS:Cu; ZnS:Mn; and ZnS:Eu designate ZnS photoluminescence fluorescent materials having ZnS as a parent body and activated by Cu and Al, Cu, Mn, and Eu, respectively. Likewise, YVO₄:Eu and YVO₄:Ce designate fluorescent materials having YVO₄ as a parent body and activated by Eu and Ce, respectively. Likewise, Y₂O₂S:Eu and Y₂O₂S:Ce designate fluorescent materials having Y₂O₂S as a parent body and activated by Eu and Ce, respectively. Each of these fluorescent materials has an absorption spectrum with respect to light ranging from blue to green, and emits light with the wavelength longer than excitation wavelength.

When the light-emitting device emits light ranging from blue to green, ZnS:Eu; YVO₄:Ce; and Y₂O₂S:Ce of the above-mentioned fluorescent materials are longer in emission wavelength in response to blue to green excitation light than any other fluorescent material. That is, light emitted from these fluorescent materials is red. As a result, light obtained by mixing the light emitted from these fluorescent materials and light from the light-emitting device as a primary light source turns color closer to white. Thus, to obtain an emission color closer to white, it is preferable that one fluorescent material or two or more fluorescent materials selected from ZnS:Eu; YVO₄:Ce; and Y₂O₂S:Ce are selected as the fluorescent materials.

Alternatively, CaS:Eu may be used as the fluorescent material. Red fluorescence is obtained by such a fluorescent material.

Further, as disclosed in Japan Patent No. 2927279, an yttrium-aluminum-garnet fluorescent material activated by cerium may be used. The activation by cerium may be omitted. In the yttrium-aluminum-garnet fluorescent material, a part or the whole of yttrium may be replaced at least one element selected from the group of Lu, Sc, La, Gd and Sm, or a part or the whole of aluminum may be replaced by either Ga or In or both of Ga and In. Further in detail, the fluorescent material is expressed by (RE₁₋ₓSmₓ)₃(Al_{y}Ga_{1-y})₅O₁₂:Ce (where 0≦x<1, 0≦y≦1, and RE designates at least one kind selected from Y and Gd). In this case, light emitted from the group III nitride compound semiconductor light-emitting device is preferably set to have a peak wavelength in a range of from 400 nm to 530 nm.

In the embodiments, an yttrium-aluminum-garnet fluorescent material is used as the fluorescent material.

It is preferable that yttrium-aluminum-garnet:Ce; ZnS:Cu, Al; ZnS:Cu; ZnS:Mn; ZnS:Eu; or the like, is adopted as the fluorescent material for a light-emitting device having a peak wavelength near 380 nm (for example, a light-emitting diode with a wavelength of 382 nm provided by TOYODA GOSEI CO., LTD., or the like).

Such a fluorescent material is preferably dispersed into the light-transmissible member uniformly. In the light-transmissible member, an inclination may be provided in the dispersion density of the fluorescent material, or such an inclination may be changed gradually or distributed unevenly.

Next, description will be described about the mode for carrying out the present invention.

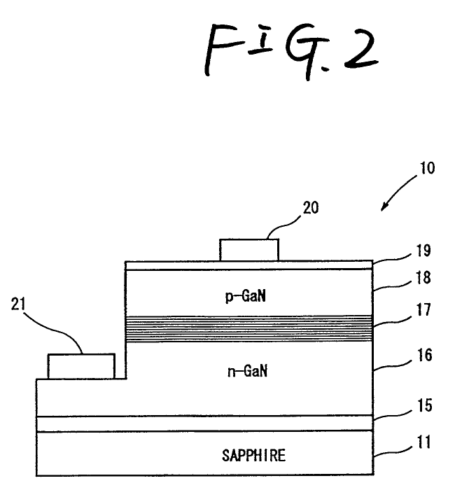

First, description will be made about a light-emitting device to be used in the embodiments of the present invention. A light-emitting diode 10 the configuration of which is shown in FIG. 2 is adopted as the light-emitting device.

The specifications of respective layers are as follows.

| | |
|---|---|
| Layer | composition |
| Electrode material layer 19 | p-GaN:Mg |
| p-type layer 18 | |
| Layer 17 containing | containing a layer of |
| a light-emitting layer | InGaN |
| n-type layer 16 | n-GaN:Si |
| Buffer layer 15 | AlN |
| Substrate 11 | |

In the above configuration, the n-type layer 16 may be of a double-layered structure having an n⁻ layer of low electron concentration on the layer 17 containing a light-emitting layer side and an n⁺ layer of high electron concentration on the buffer layer 15 side. The latter is called an n-type contact layer.

The structure of the layer 17 containing a light-emitting layer is not limited to a multiple quantum well structure. A single hetero type structure, a double hetero type structure or a homo junction type structure may be used as the structure of the light-emitting device. Alternatively, as the layer containing a light-emitting layer, a single quantum well structure may be used.

A group III nitride compound semiconductor layer doped with an acceptor such as magnesium and having a wide band gap may be interposed between the layer 17 containing a light-emitting layer and the p-type layer 18. This interposition is provided for effectively preventing electrons imparted into the layer 17 containing a light-emitting layer from diffusing into the p-type layer 18.

The p-type layer 18 may be of a double-layered structure having a p⁻ layer of low hole concentration on the layer 17 containing a light-emitting layer side and a p⁺ layer of high hole concentration on the electrode side. The latter is called a p-type contact layer.

When the layer 17 containing a light-emitting layer has a quantum well structure, the quantum well structure layer of the quantum well structure may be composed of InGaAlN including InN, GaN, InGaN and InAlN. A barrier layer may be composed of InGaAlN including GaN, InGaN, InAlN and AlGaN so long as the energy gap thereof is larger than that of the quantum well structure layer.

The light-emitting diode configured thus is manufactured as follows.

First, the temperature of the sapphire substrate is raised up to 1,130° C. and the surface of the sapphire substrate is cleaned while hydrogen gas is circulated into a reactor of an MOCVD apparatus.

After that, at the substrate temperature, TMA and NH₃ are introduced to grow the buffer layer 15 of AlN by an MOCVD method.

Next, the n-type layer 16 is formed in the state where the substrate temperature is maintained, and the layer 17 containing a light-emitting layer and the p-type layer 18 following the n-type layer 16 are formed in accordance with the conventional method (MOCVD method). In the growth method, an ammonia gas and group III element alkyl compound gases such as trimethylgallium (TMG), trimethylaluminum (TMA) and trimethylindium (TMI) are supplied onto a substrate heated to a suitable temperature and are subjected to a thermal decomposition reaction to thereby make a desired crystal grown on the substrate.

Next, parts of the p-type layer 18, the layer 17 containing a light-emitting layer and the n-type layer 16 are removed by use of Ti/Ni as a mask by reactive ion etching so as to expose the n-type layer (also used as an n-type contact layer) 16 on which an n-type seat electrode 21 is to be formed.

Photo-resist is applied uniformly onto the semiconductor surface, and the photo-resist on the p-type layer 18 (also used as a p-type contact layer) is removed by photolithography. Co (cobalt, 1.5 nm) and Au (gold, 6.0 nm) are deposited sequentially on the exposed p-type layer 18 so as to form an electrode 19. Incidentally, it is preferable that this electrode is formed to be light-transmissible. Next, a p-type seat electrode 20 and the n-type seat electrode 21 are deposited likewise.

After that, heat treatment is carried out, and chips are cut out from the wafer. Thus, a light-emitting device shown in FIG. 2 is obtained.

(First Embodiment)

FIG. 3 shows the configuration of a light-emitting unit 30 in this first embodiment. In the light-emitting unit 30, there are used a mount frame 3 and a lead frame 7 which are the same as those used in the conventional example. A shell-like molded member 35 may be the same as that in the conventional example.

In this embodiment, epoxy resin is charged into a recess portion 4 of the mount frame 3 so as to form a light-transmissible member 31. The sapphire substrate of the light-emitting device 10 is fixed to the surface of the light-transmissible member 31 through a transparent adhesive agent. It is preferable that the respective centers of the light-emitting device 10, the recess portion 4 and the molded member 35 are located on the same axis. The center line of the molded member 35 coincides with the optical axis of the light-emitting unit 30. The molded member 35 may be also formed out of the same epoxy resin as the light-transmissible member 31. The p-type seat electrode 20 of the light-emitting device 10 is connected to the lead frame 7 through a conductive wire 33. Likewise, the n-type seat electrode 21 is connected to the mount frame 3 through a conductive wire 34.

According to the light-emitting unit 30 configured thus, of light generated in the layer 17 containing a light-emitting layer, a light component directed toward the sapphire substrate is transmitted through the sapphire substrate as it is. Then, the light component is further transmitted through the light-transmissible member 31 and reflected toward the optical axis direction by the reflection surface 32 of the recess portion 4. The reflected light is further transmitted through the light-transmissible member 31 and emitted from the recess portion 4. The light emitted from the recess portion 4 travels in the molded member 35 and is refracted in a hemispherical leading edge portion of the molded member 35. The curvature of the hemispherical leading edge portion is designed suitably to obtain desired optical properties. Of the light generated in the layer 17 containing a light-emitting layer, a light component directed toward the electrode is reflected by the electrode so as to be directed toward the substrate. Then, the reflected light pursues the same path described above. Incidentally, when the electrode is light-transmissible, this light is transmitted through the electrode. Then, the transmitted light travels in the molded member 35 and is refracted in the hemispherical leading edge portion of the molded member 35 suitably. Of the light generated in the layer 17 containing a light-emitting layer, the light component emitted from a side of the light-emitting device 10 is reflected by a portion of the reflection surface 32 which is not coated with the light-transmissible member 31. Then, the reflected light travels in the molded member 35 and is emitted to the outside. According to the light-emitting unit 30 in this embodiment, light emitted omnidirectionally from the layer 17 containing a light-emitting layer can be captured by the reflection layer 32.

In this embodiment, the surface of the light-transmissible member 31 is set to be lower than the circumferential edge of the recess portion 4. This is for the purpose to allow the reflection surface 32 to capture light emitted laterally from the light-emitting device 10. To this end, the circumferential edge of the recess portion 4 has to be located high in level than at least the layer 17 containing a light-emitting layer. In this embodiment, the p-type electrode 19 is set to be substantially equal in level to the circumferential edge of the recess portion 4.

(Second Embodiment)

FIG. 4 shows a light-emitting unit 40 according to a second embodiment of the present invention. Parts the same as those in FIG. 3 are referenced correspondingly, and description thereof will be omitted. In this second embodiment, a paraboloid of revolution is adopted as the surface of a recess portion 44, and designed to be filled with a light-transmissible member 41.

Incidentally, the reflection surface is not limited to such a paraboloid of revolution. A desired shape can be adopted in accordance with the optical properties required of the light-emitting unit 40.

(Third Embodiment)

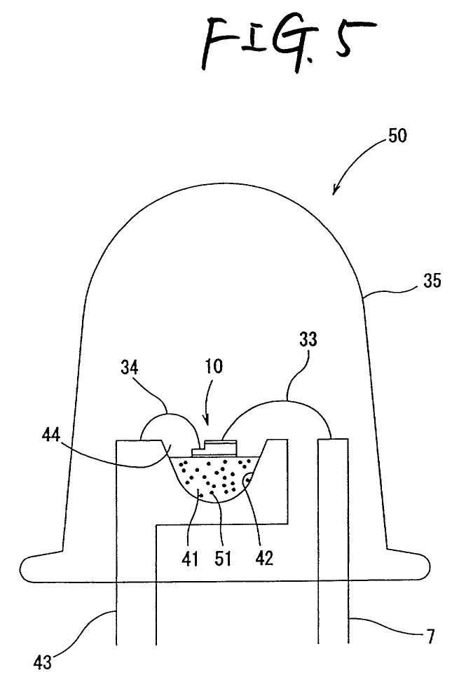

FIG. 5 shows a light-emitting unit 50 according to a third embodiment of the present invention. Incidentally, parts the same as those in FIG. 4 are referenced correspondingly, and description thereof will be omitted. In the light-emitting unit 50 in this embodiment, an yttrium-aluminum-garnet fluorescent material is dispersed uniformly in the light-transmissible member 41 in the second embodiment of FIG. 4. This fluorescent material absorbs blue light emitted from the light-emitting device 10 and emits red to orange light. When light emitted directly from the light-emitting device 10 and light emitted from the fluorescent material are mixed in the light-transmissible member 41 and the molded member 35, white light is generated.

By selecting a fluorescent material and/or a phosphor suitably as shown in this third embodiment, the color of light emitted from the light-emitting device can be changed into a desired color. A fluorescent material and/or a phosphor may be dispersed in the molded member 35.

(Fourth Embodiment)

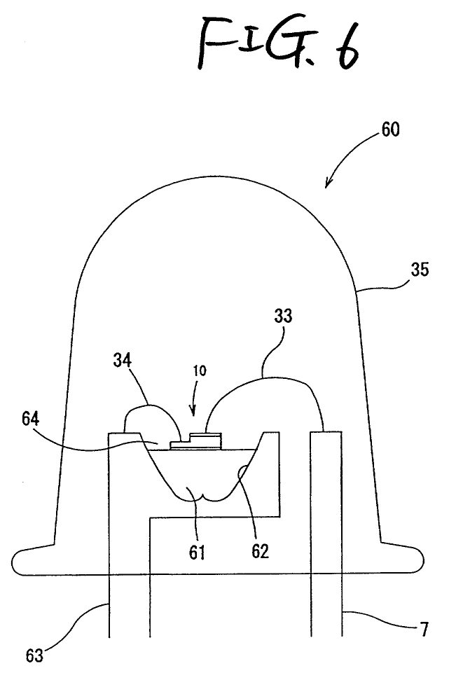

FIG. 6 shows a light-emitting unit 60 according to a fourth embodiment of the present invention. Parts the same as those in FIG. 3 are referenced correspondingly, and description thereof will be omitted. In this fourth embodiment, a plurality of focuses are provided in a surface (reflection surface 62) of a recess portion 64 of a mount frame 63, and the recess portion 64 is filled with a light-transmissible member 61. In the same manner as in the above-mentioned third embodiment, a fluorescent material and/or a phosphor may be dispersed into the light-transmissible member 61.

(Fifth Embodiment)

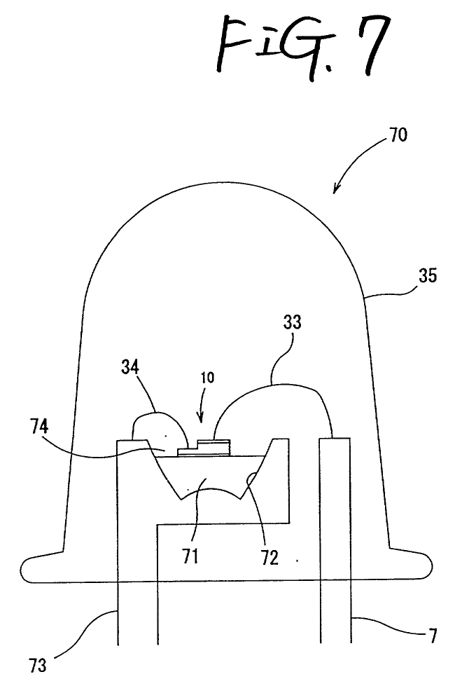

FIG. 7 shows a light-emitting unit 70 according to a fifth embodiment of the present invention. Parts the same as those in FIG. 3 are referenced correspondingly, and description thereof will be omitted. In this fifth embodiment, a bottom portion of a surface (reflection surface 72) of a recess portion 74 of a mount frame 73 is formed into a convex surface. As a result, a variation can be given to reflected light. The recess portion 74 is filled with a light-transmissible member 71. In the same manner as in the above-mentioned third and fourth embodiments, a fluorescent material and/or a phosphor may be dispersed in the light-transmissible member 71.

The present invention is not limited to the mode for carrying out the present invention and the embodiments of the invention and the description thereof at all. Various modifications which can be easily conceived by those skilled in the art may be contained in the present invention without departing from the description of the scope of claim.

It is confirmed that the following items are disclosed in the present application.

A mount frame for a group III nitride compound semiconductor light-emitting device, comprising a recess portion which is a paraboloid of revolution.

A method for mounting a light-emitting device, comprising the steps of: filling a recess portion of a mount frame with a light-transmissible member and solidifying the light-transmissible member, and fixing a light-transmissible substrate of a light-emitting device to the surface of the light-transmissible member.

A method for manufacturing a light-emitting unit, comprising the steps of: filling a recess portion of a mount frame with a light-transmissible member and solidifying the light-transmissible member, and fixing a light-transmissible substrate of a light-emitting device to the surface of the light-transmissible member.

What is claimed is:

1. A light-emitting unit comprising:
a mount frame having a reflection surface and a light-transmissible member covering said reflection surface; and
a group III nitride compound semiconductor light-emitting device mounted on said mount frame;
wherein a substrate of said light-emitting device is fixed to a surface of said light-transmissible member so that light emitted from said light-emitting device is transmitted through said substrate and reflected by said reflection surface.

2. A light-emitting unit according to claim 1, wherein a recess portion is formed in said mount frame so that a surface of said recess portion is formed as said reflection surface, and said recess portion is filled with said light-transmissible member.

3. A light-emitting unit according to claim 2, wherein an opening portion of said recess portion is directed in an optical axis of said light-emitting unit.

4. Alight-emitting unit according to claim 1, wherein said reflection surface is a paraboloid of revolution around said light-emitting device.

5. A light-emitting unit according to claim 1, wherein light emitted from a side surface of said light-emitting device is reflected by said reflection surface.

6. A light-emitting unit according to claim 1, wherein an edge of said reflection surface is located ahead of a light-emitting layer containing layer of said light-emitting device in an optical axis of said light-emitting unit.

7. A light-emitting unit according to claim 1, wherein a fluorescent material is dispersed into said light-transmissible member.

8. A light-emitting unit according to claim 1, wherein said mount frame is coated with a light-transmissible sealing member, and said sealing member is formed out of the same material as that of said light-transmissible member.

9. A light-emitting unit comprising:
a mount frame having a recess portion and a light-transmissible member charged into said recess portion; and
a group III nitride compound semiconductor light-emitting device mounted on said mount frame;
wherein a sapphire substrate of said light-emitting device is fixed to a surface of said light-transmissible member so that light transmitted through said sapphire substrate is transmitted through said light-transmissible member, reflected by a surface of said recess portion, further transmitted through said light-transmissible member, and emitted to the outside of said recess portion.
